(19) United States
(12) Patent Application Publication
(10) Pub. No.: US 2007/0030744 A1
(43) Pub. Date: Feb. 8, 2007

(54) Semiconductor memory device

(75) Inventors: Toshihiro Nakamura, Kyoto (JP); Naoki Kuroda, Kyoto (JP); Masanobu Hirose, Kyoto (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/487,976

(22) Filed: Jul. 18, 2006

(30) Foreign Application Priority Data
Jul. 22, 2005 (JP) 2005-212042

(51) Int. Cl. G11C 7/00

(52) U.S. Cl. 365/203

(57) ABSTRACT

Source potential connection transistors, each supplying a source control potential from a source potential wiring to a source node, are disposed so as to be dispersed in a memory cell array. In addition, a source potential control circuit is disposed inside a row decoder block. With this configuration, the number of the cells connected to each word line can be increased, and the area of the memory core can be reduced. Furthermore, the pattern shape of the diffusion layer constituting the source potential connection transistor is made the same as that of the diffusion layer of a memory cell transistor, whereby mask creation can be facilitated.

### BACKGROUND OF THE INVENTION

1. Field of the Invention

The present invention relates to a semiconductor memory device, such as a mask ROM (read-only memory). More particularly, the present invention relates to a layout technology for a semiconductor memory device, capable of increasing the capacity of the memory core thereof and capable of facilitating the mask pattern creation for the memory cell array region thereof.

2. Prior Art

FIG. 8 is a block diagram showing the configuration of the core of a contact-type mask ROM, serving as an example of a prior art of a semiconductor memory device.

The contact-type mask ROM is a mask ROM in which memory data corresponds to “0” or “1” depending on whether the drain node of a memory cell transistor is connected to a bit line or not.

In FIG. 8, this semiconductor memory device comprises a memory cell array 28, a row decoder block 29, a data router block 30, and a peripheral control circuit 31. Inside the row decoder block 29, a source potential control circuit 32 is disposed. Inside the memory cell array 28, multiple memory cells 33 are disposed in the row and column directions.

To the gates of the memory cell transistors constituting the memory cells 33, a word line (N-1 th) 34 and a word line (N th) 35 are connected. Furthermore, to the drains of the memory cell transistors constituting the memory cells 33, a bit line (N-1 th) 36 and a bit line (N th) 37 are connected. To the sources of the memory cell transistors constituting the memory cells 33, a source control signal line 38, the potential of which is controlled using the source potential control circuit 32, is connected.

A bit line contact 39 that connects the drain of the memory cell transistor constituting the memory cell 33 to each bit line is provided. In addition, a source contact 40 that connects the source of the transistor constituting the memory cell 33 to the source control signal line 38 is provided. In the memory cell array 28, the memory cells 33, each formed of an N-channel MOS transistor, are disposed in a matrix form.

The prior art of the semiconductor memory device will be described below referring to FIG. 8.

The semiconductor memory device is configured as described below to reduce a steady-state current that is generated when an off-leak current flows from the source node of the memory cell 33. In other words, using the source potential control circuit 32 disposed inside the row decoder block 29 shown in FIG. 8, the source control signal line 38 is controlled so as to have the ground potential or a desired potential other than the ground potential. With this configuration, when the word line (N th) 35 is selected, the off-leak currents flowing to the source control signal line 38 from the source nodes of the memory cells connected to the other unselected word lines are reduced (refer to Japanese Patent Application Laid-Open No. 2003-317494).

Because of the prior art of the semiconductor memory device described above, the steady-state currents inside the memory cell array 28 can be reduced. Hence, it is possible to increase the number of memory cells to be connected to one bit line.

However, the source potential control circuit 32 that controls the source nodes is disposed inside the row decoder block 29. For this reason, for example, in the case that the memory cell array 28 is relatively large and that the number of the memory cells to be connected to the word lines is large, the potentials at the source nodes of the memory cells disposed on the opposite side of the row decoder block 29 across the memory cell array 28 cannot be controlled sufficiently within a predetermined period because of the influences of wiring delay or the like. As a result, the leak currents are not reduced sufficiently once in a while. Therefore, it is difficult to carry out memory operation sufficiently in the large-scale memory cell array 28 and to realize further reduction in the area of the memory core.

Generally speaking, the memory core described above is a region in which the same pattern for memory cell arrays, sense amplifiers, row decoders, etc. is disposed repeatedly inside a semiconductor memory device. In other words, the memory core is a region excluding peripheral control circuits, and a region in which the reduction in the area of a unit block is very effective in the reduction in the area of the whole of the semiconductor memory device because the unit block is disposed repeatedly.

### SUMMARY OF THE INVENTION

The present invention is devised to solve the problems encountered in the prior art of the semiconductor memory device described above, and is intended to provide a semiconductor memory device layout technology capable of reducing the whole area of even a large memory core and reducing chip cost owing to area reduction by decreasing the off-leak currents of the memory cells connected to the bit lines and by increasing the number of the memory cells connected to each word line, and capable of facilitating patterning at the time when the mask for the memory cell array is created.

For the purpose of solving the above-mentioned problems, the semiconductor memory device according to the present invention has a configuration in which a circuit that controls the potential at the source node of a memory cell to a desired potential is disposed in the row decoder block and the memory cell array thereof.

A first semiconductor memory device according to the present invention comprises a memory cell array in which multiple memory cells, each including a memory cell transistor, are disposed in a matrix form in the row and column directions; word lines, each of which is commonly connected to each row of the gates of the memory cell transistors included in the multiple memory cells; bit lines, each of which is commonly connected to each column of the drains of the memory cell transistors included in the multiple memory cells; source lines, each of which is commonly connected to each row of the sources of the memory cell transistors included in the multiple memory cells; a source potential control circuit that selectively controls the potentials of the source lines according to a row selection signal that is used to select the word lines; source potential supplying lines disposed in the column direction inside the memory cell array to supply the potentials controlled using the source potential control circuit to the memory cell array; and source potential connection transistors, the drains of which are connected to the source potential supplying lines, the sources of which are connected to the source lines, and which selectively control the potentials of the source lines according to the row selection signal.

In addition, the source potential control circuit controls the potentials of the source lines connected to the memory cells not selected using the row selection signal to potentials different from the potential of the source line connected to the memory cell selected using the row selection signal so that the off-leak currents of the memory cell transistors included in the non-selected memory cells are decreased. Furthermore, the source potential supplying line and the source potential connection transistor are disposed between the memory cells disposed in the row direction, and also disposed for every constant number of the memory cells in the column direction. Still further, the shape of the diffusion layer constituting the source potential connection transistor in the column direction is the same as the shape of the diffusion layer constituting the memory cell in the column direction.

A single or multiple source potential connection transistors are disposed inside the memory cell array and are used to connect the potential of the source line connected to the memory cell selected using the row selection signal to the ground potential or a desired potential other than the ground potential. Furthermore, for example, the length of the mask shape of the diffusion layer constituting the source potential connection transistor, in the column direction, is the same as that of the mask shape of the diffusion layer constituting the memory cell transistor, in the column direction.

In the first semiconductor memory device according to the present invention, the power supply wirings for controlling the source potentials of the memory cell transistors to a desired potential are disposed inside the memory cell array. The source potential connection transistor between the power supply wiring and the memory cell transistor is disposed so as to be dispersed inside the memory cell array. With this configuration, the length of the source potential control signal line that controls the source potential of each memory cell transistor is made larger, and the number of the gates of the memory cell transistors being connected to one word line increases. Hence, even when the wiring resistance of the source potential control signal line increases, the desired potential can be supplied evenly to the sources of the memory cell transistors inside the memory cell array using the power supply wirings and the source potential connection transistors being disposed so as to be dispersed. Therefore, numerous memory cells can be connected to each word line, and the semiconductor memory device can be made large easily. Furthermore, the mask pattern creation for the memory cell array, requiring fine adjustment, can be facilitated, and the yield of the mask for a system LSI chip including a memory core can be improved by making the shape of the diffusion layer of the source potential connection transistor in the column direction the same as the shape of the diffusion layer of the memory cell transistor in the column direction and by maintaining the repetition of the shape pattern of the diffusion layer inside the memory cell array in the column direction even in regions other than the memory cell array.

A second semiconductor memory device according to the present invention is characterized in that, in the first semiconductor memory device according to the present invention, the source potential connection transistor is a MOS transistor comprising a diffusion layer obtained by carrying out the same injection as that for the memory cell transistor.

In the second semiconductor memory device according to the present invention, each of the source potential connection transistors disposed so as to be dispersed inside the memory cell array is formed of a transistor having a diffusion layer obtained by carrying out the same injection as that carried out for the diffusion layer constituting the memory cell transistor. Hence, no injection-separation region is required inside the memory cell array. Therefore, in addition to effects similar to those of the first semiconductor memory device according to the present invention, the memory core can be made larger.

A third semiconductor memory device according to the present invention is characterized in that, in the first semiconductor memory device according to the present invention, a row decoder including a circuit that creates the row selection signal for word line selection is disposed adjacent to the memory cell array, and that the source potential control circuits are disposed at multiple positions inside the row decoder block and on the opposite side of the row decoder block across the memory cell array.

In the third semiconductor memory device according to the present invention, the source potential control circuits are disposed on both sides of the memory cell array. Hence, even when the memory cell array is large and the source lines are long, the delay in the control of the source potential due to the wiring resistance of the source line can be reduced. Therefore, in addition to effects similar to those of the first semiconductor memory device according to the present invention, the memory core can be made larger.

A fourth semiconductor memory device according to the present invention is characterized in that, in the first semiconductor memory device according to the present invention, the substrate contacts of the memory cell transistor are disposed inside the memory cell array in the column direction, that the shape of the diffusion layer in the column direction on which the substrate contacts are disposed is the same as the shape of the diffusion layer of the memory cell transistor in the column direction, and that the source potential connection transistor is disposed at the same position as that of the substrate contact wiring that is disposed inside the memory cell array in the column direction as a wiring for connecting the substrate contacts.

In the fourth semiconductor memory device according to the present invention, each of the source potential connection transistors disposed so as to be dispersed inside the memory cell array is disposed at the position in which the substrate contact wiring of the memory cell transistor is disposed. Hence, the area can be reduced further in comparison with the configuration in which the source potential connection transistor is disposed separately from the substrate contact wiring. Therefore, in addition to effects similar to those of the first semiconductor memory device according to the present invention, the memory core can be made larger.

A fifth semiconductor memory device according to the present invention is characterized in that, in the first semiconductor memory device according to the present invention, a word line back-wiring is disposed to reduce the wiring resistances of the word lines, that the connection contact regions for connecting the word line back-wirings to the word lines are disposed inside the memory cell array in the column direction, and that the source potential connection transistors are disposed at the same positions as those of the connection contact regions.

In the fifth semiconductor memory device according to the present invention, each of the source potential connection transistors disposed so as to be dispersed inside the memory cell array is disposed at the position in which a connection contact is disposed, the position being between the word line and the word line back-wiring disposed to reduce the wiring resistance of the word line. Hence, the area can be reduced further in comparison with the configuration in which the source potential connection transistor is disposed separately from the contact. Therefore, in addition to effects similar to those of the first semiconductor memory device according to the present invention, the memory core can be made larger.

A sixth semiconductor memory device according to the present invention is characterized in that, in the first semiconductor memory device according to the present invention, the substrate contacts of the memory cell transistor are disposed inside the memory cell array in the column direction, that a word line back-wiring is disposed to reduce the wiring resistances of the word lines, that the connection contact regions for connecting the word line back-wirings to the word lines are disposed inside the memory cell array in the column direction, that the shape of the diffusion layer in the column direction on which the substrate contacts are disposed is the same as the shape of the diffusion layer of the memory cell transistor in the column direction, and that the source potential connection transistors and the substrate contact wirings being disposed inside the memory cell array in the column direction and serving as the substrate contacts are disposed alternately for every constant number of rows.

In the sixth semiconductor memory device according to the present invention, even when an injection-separation region in which injection being different from the injection for the memory cells is required to dispose the substrate contacts, the separation region is used as a space in which the back-wiring connection contacts are disposed. Hence, the increase in the area can be suppressed. Therefore, in addition to effects similar to those of the first semiconductor memory device according to the present invention, the area of the memory core can be made larger.

A seventh semiconductor memory device according to the present invention is characterized in that, in the first semiconductor memory device according to the present invention, the potential supplied to the source line connected to the memory cell selected using the row selection signal in the source potential control circuit is set to the ground potential.

In the seventh semiconductor memory device according to the present invention, the potential supplied to the source line connected to the memory cell selected using the row selection signal is set to the ground potential, and no power supply generating circuit for generating a desired potential is required. Hence, the area of the memory core can be reduced. Therefore, in addition to effects similar to those of the first semiconductor memory device according to the present invention, the memory core can be made larger.

An eighth semiconductor memory device according to the present invention is characterized in that, in the first semiconductor memory device according to the present invention, the potential supplied to the source line connected to the memory cell selected using the row selection signal in the source potential control circuit is supplied from mesh wirings formed of one wiring layer disposed inside the memory cell array.

In the eighth semiconductor memory device according to the present invention, the potentials supplied to the source lines are supplied from the mesh wirings formed inside the memory cell array using one wiring layer. Therefore, in addition to effects similar to those of the first semiconductor memory device according to the present invention, the voltage drop of the potentials supplied to the source lines can be suppressed.

A ninth semiconductor memory device according to the present invention is characterized in that, in the first semiconductor memory device according to the present invention, the potential supplied to the source line connected to the memory cell selected using the row selection signal in the source potential control circuit is supplied from mesh wirings formed of multiple wiring layers disposed inside the memory cell array.

In the ninth semiconductor memory device according to the present invention, the potentials supplied to the source lines are supplied from the mesh wirings disposed inside the memory cell array using multiple wiring layers. Therefore, in addition to effects similar to those of the first semiconductor memory device according to the present invention, the voltage drop of the potentials supplied to the source lines can be suppressed.

A 10th semiconductor memory device according to the present invention is characterized in that, in the first semiconductor memory device according to the present invention, for example, the lengths of the mask shapes of the diffusion layer constituting the source potential connection transistor, in the row and column directions, are the same as the lengths of the mask shapes of the diffusion layer constituting the memory cell transistor, in the row and column directions.

In the 10th semiconductor memory device according to the present invention, the shapes of the diffusion layer of the source potential connection transistor in the row and column directions are the same as the shapes of the diffusion layer of the memory cell transistor in the row and column directions. Hence, the shape patterns of the memory cell diffusion layers in the source potential connection transistors are exactly the same, and mask creation is facilitated. Therefore, in addition to effects similar to those of the first semiconductor memory device according to the present invention, the yield can be improved further.

An 11th semiconductor memory device according to the present invention is characterized in that, in the fourth semiconductor memory device according to the present invention, for example, the lengths of the mask shapes of the diffusion layer constituting the source potential connection transistor, in the row and column directions, are the same as the lengths of the mask shapes of the diffusion layer constituting the memory cell transistor, in the row and column directions.

In the 11th semiconductor memory device according to the present invention, the shapes of the diffusion layer of the source potential connection transistor in the row and column directions are the same as the shapes of the diffusion layer of the memory cell transistor in the row and column directions. Hence, the shape patterns of the memory cell diffusion layers in the source potential connection transistors are exactly the same, and mask creation is facilitated. Therefore, in addition to effects similar to those of the fourth semiconductor memory device according to the present invention, the yield can be improved further.

A 12th semiconductor memory device according to the present invention is characterized in that, in the sixth semiconductor memory device according to the present invention, for example, the lengths of the mask shapes of the diffusion layer constituting the source potential connection transistor, in the row and column directions, are the same as the lengths of the mask shapes of the diffusion layer constituting the memory cell transistor, in the row and column directions.

In the 12th semiconductor memory device according to the present invention, the shapes of the diffusion layer of the source potential connection transistor in the row and column directions are the same as the shapes of the diffusion layer of the memory cell transistor in the row and column directions. Hence, the shape patterns of the memory cell diffusion layers in the source potential connection transistors are exactly the same, and mask creation is facilitated. Therefore, in addition to effects similar to those of the sixth semiconductor memory device according to the present invention, the yield can be improved further.

A 13th semiconductor memory device according to the present invention is characterized in that, in the fourth semiconductor memory device according to the present invention, for example, the lengths of the mask shapes of the diffusion layer on which the substrate contacts are disposed, in the row and column directions, are the same as the lengths of the mask shapes of the diffusion layer of the memory cell transistor, in the row and column directions.

In the 13th semiconductor memory device according to the present invention, the shapes of the diffusion layer of the substrate contact of the memory cell in the row and column directions are the same as the shapes of the diffusion layer of the memory cell transistor in the row and column directions. Hence, the shape patterns of the memory cell diffusion layers in the substrate contacts are exactly the same, and mask creation is facilitated. Therefore, in addition to effects similar to those of the fourth semiconductor memory device according to the present invention, the yield can be improved further.

A 14th semiconductor memory device according to the present invention is characterized in that, in the sixth semiconductor memory device according to the present invention, for example, the lengths of the mask shapes of the diffusion layer on which the substrate contacts are disposed, in the row and column directions, are the same as the lengths of the mask shapes of the diffusion layer constituting the memory cell transistor, in the row and column directions.

In the 14th semiconductor memory device according to the present invention, the shapes of the diffusion layer of the substrate contact of the memory cell in the row and column directions are the same as the shapes of the diffusion layer of the memory cell transistor in the row and column directions. Hence, the shape patterns of the memory cell diffusion layers in the substrate contacts are exactly the same, and mask creation is facilitated. Therefore, in addition to effects similar to those of the sixth semiconductor memory device according to the present invention, the yield can be improved further.

A 15th semiconductor memory device according to the present invention is characterized in that, in the first semiconductor memory device according to the present invention, for example, the lengths of the mask shapes of the diffusion layer constituting the source potential connection transistor, and the wiring width and pitch of the source potential wirings in the row and column directions are the same as the lengths of the mask shapes of the diffusion layer constituting the memory cell transistor, and the wiring width and pitch of the bit lines in the row and column directions.

In the 15th semiconductor memory device according to the present invention, the shape patterns of the diffusion and wiring layers in which the source potential connection transistors are disposed are the same as the shape patterns of the diffusion and wiring layers in which the memory cell transistors are disposed. Hence, the mask creation for the diffusion and wiring layers is facilitated. Therefore, in addition to effects similar to those of the first semiconductor memory device according to the present invention, the yield can be improved further.

A 16th semiconductor memory device according to the present invention is characterized in that, in the first semiconductor memory device according to the present invention, one or more source potential connection transistors are disposed in a data output unit block for the memory cells. In other words, one or more source potential connection transistors are disposed in one unit block that outputs data from the memory to the outside of the memory for every constant number of the bit lines in the column direction.

In the 16th semiconductor memory device according to the present invention, one or more source potential connection transistors are disposed in one unit block for memory data output. Hence, potential control using the source potential connection transistors is possible for each unit block for data output. Therefore, compiling for each unit block for data output in the memory cell array is facilitated.

The meaning of compiling will be described herein. Compiling means the changeability in the setting of memory capacity. For example, when a semiconductor memory device having a capacity of 1 Mb is designed, memory cell array blocks or the like are designed beforehand in units of a certain memory capacity (for example, in 128 Kb increments). For example, when a semiconductor memory device having a capacity of 512 Kb is required, the number of the blocks being designed in 128 Kb increments as described above is increased or decreased, and the control of the peripheral control circuit is changed slightly. In this way, semiconductor memory devices having different capacities can be made easily. The meaning that semiconductor memory devices having different capacities can be made easily is referred to as “compiling is easy.”

As described above, in the semiconductor memory device according to the present invention, the power supply wirings for controlling the source potentials of the memory cell transistors to a desired potential are disposed inside the memory cell array. The source potential connection transistors, each of which is disposed between the power supply wiring and the memory cell transistor, are disposed so as to be disposed so as to be dispersed inside the memory cell array. With this configuration, the length of the source potential control signal line for controlling the source potential of each memory cell transistor is extended, and the number of the gates of the memory cell transistors to be connected to one word line increases. Hence, even if the wiring resistance of the source potential control signal line increases, the desired potential can be supplied evenly to the sources of the memory cell transistors inside the memory cell array using the power supply wirings and the source potential connection transistors being disposed so as to be dispersed. Therefore, numerous memory cells can be connected to each word line, and the semiconductor memory device can be made larger easily. In addition, the shape of the diffusion layer of the source potential connection transistor in the column direction is made the same as the shape of the diffusion layer of the memory cell transistor in the column direction, and the pattern repetition in the column direction of the shape pattern of the diffusion layer inside the memory cell array is maintained in regions other than the memory cell array. As a result, the mask pattern creation for the memory cell array, requiring fine adjustment, is facilitated, and the yield of the masks for system LSI chips including memory cores can be improved.

### BRIEF DESCRIPTION OF THE DRAWINGS

FIG. 1 is a layout diagram showing the configuration of a semiconductor memory device according to a first embodiment of the present invention;

FIG. 2 is a layout diagram showing the configuration of a semiconductor memory device according to a second embodiment of the present invention;

FIG. 3 is a layout diagram showing the configuration of a semiconductor memory device according to a third embodiment of the present invention;

FIG. 4 is a layout diagram showing the configuration of a semiconductor memory device according to a fourth embodiment of the present invention;

FIG. 5 is a layout diagram showing the configuration of a semiconductor memory device according to a fifth embodiment of the present invention;

FIG. 6 is a layout diagram showing the configuration of a semiconductor memory device according to a sixth embodiment of the present invention;

FIG. 7 is a layout diagram showing the configuration of a semiconductor memory device according to a seventh embodiment of the present invention; and

FIG. 8 is a layout diagram showing the configuration of the semiconductor memory device according to the prior art.

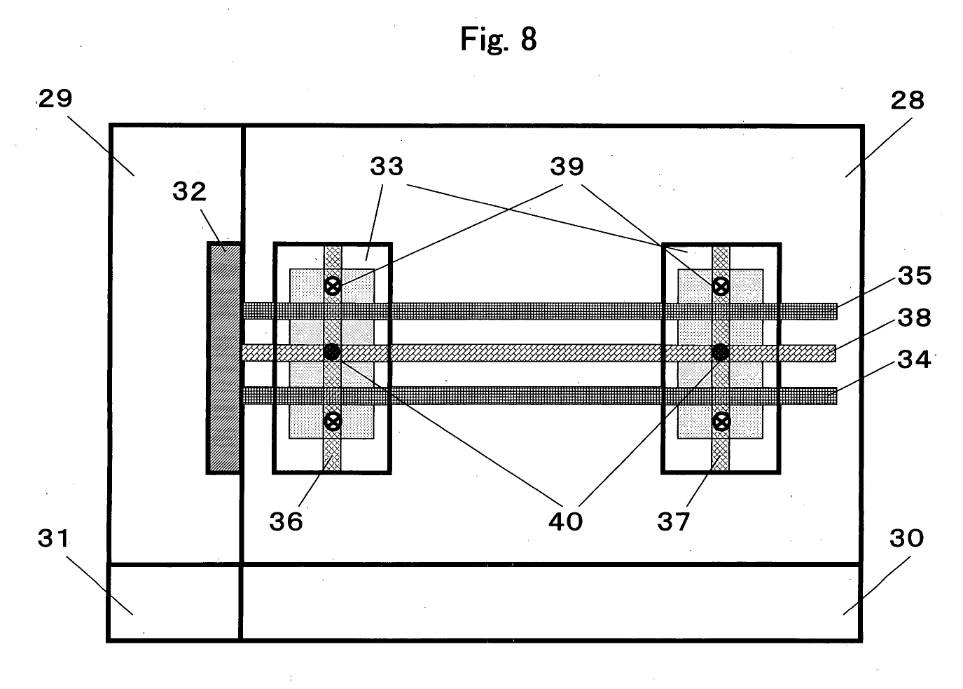

### PREFERRED EMBODIMENTS

### First Embodiment

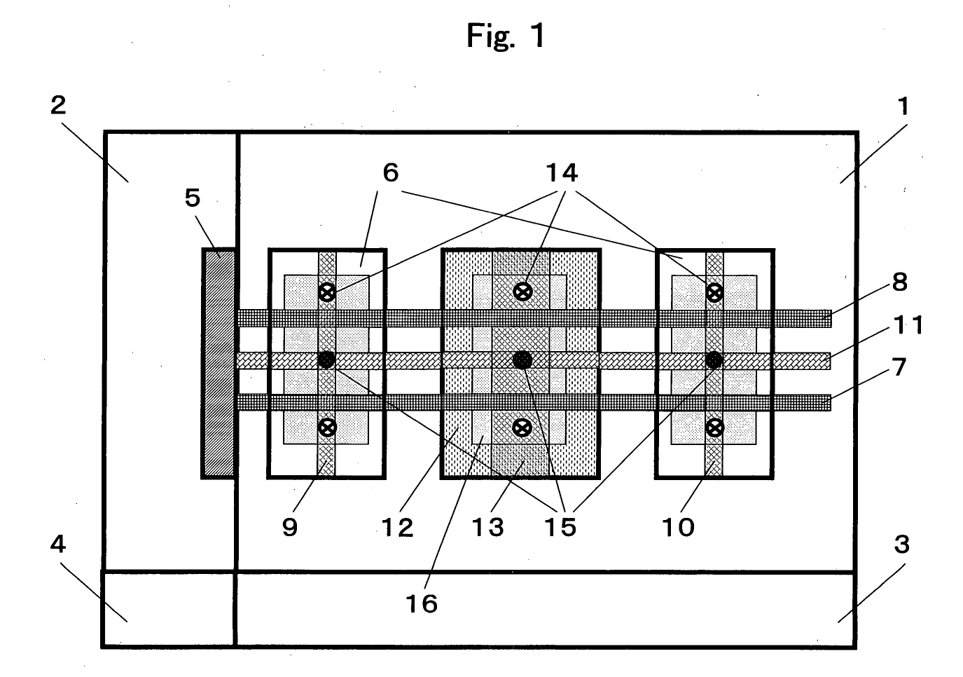

FIG. 1 is a layout diagram showing the configuration of a semiconductor memory device according to a first embodiment of the present invention.

In FIG. 1, this semiconductor memory device comprises a memory cell array 1, a row decoder block 2, a data router block 3, a peripheral control circuit 4, a source potential control circuit 5, memory cells 6, a word line (N-1 th) 7, a word line (N th) 8, a bit line (N-1 th) 9, a bit line (N th) 10, a source potential control signal line 11, a source potential connection transistor 12, a source potential wiring 13, bit line contacts 14, source contacts 15, and a source potential connection transistor diffusion layer 16.

In the row and column directions, i and j memory cells 6 are disposed, respectively, so as to constitute the memory cell array 1. The source potential connection transistor 12 is disposed for every constant number of the memory cells 6 in the column direction. The source potential control circuits 5, the memory cells 6 and the source potential connection transistors 12, j in number respectively, are disposed in the column direction. In addition, the sources are common in the word line (N-1 th) 7 and the word line (Nth) 8. Furthermore, the source potential wiring 13 is connected to a ground power supply inside the memory core. Still further, the memory cell 6 and the source potential connection transistor 12 are each formed of an N-channel MOS transistor. Moreover, the shape and the size of the source potential connection transistor diffusion layer constituting the source potential connection transistor 12, in the column direction, are the same as those of the diffusion layer of the memory cell transistor constituting the memory cell 6, in the column direction.

The semiconductor memory device configured as described above will be described below.

When the word line (N th) 8 is selected using a row selection signal generated in the row decoder block 2, the potential of the source potential control signal line 11 is controlled to the ground potential using the row selection signal or the like in the source potential control circuit 5 connected to the word line (N-1 th) 7 and the word line (Nth) 8. Because the word line (N th) 8 is selected, the source potential connection transistor 12 is turned ON. Hence, the source potential control signal line 11 is connected to the ground potential. The bit line 9 in the cell in which the bit line contacts 14 are disposed beforehand in the memory cell transistor inside the memory cell 6 is also connected to the ground potential, and data “0” is read. On the other hand, the potential of the bit line in a cell in which the bit line contacts 14 are not disposed beforehand remains having a precharged potential, and data “1” is read.

At this time, the following effect is obtained because the source potential control circuit 5 is disposed inside the row decoder block 2, and because the source potential connection transistor 12 is disposed so as to be dispersed for every constant number of columns inside the memory cell array 1. When the number of the memory cells 6 being disposed increases in the row direction, that is, even when the length of the source potential control signal line 11 is extended, the potential of the source potential control signal line 11, at a position away from the source potential control circuit 5, can be quickly switched to the ground potential using the source potential wiring 13 being disposed so as to be dispersed inside the memory cell array 1. As a result, more memory cells 6 to be disposed inside the memory cell array 1 can be disposed in the row direction, and the semiconductor memory device can be made larger in size.

In addition, because the source potential connection transistor 12 is formed of an N-channel MOS transistor as in the case of the memory cell transistor constituting the memory cell 6, it is not necessary to provide any MOS injection-separation region between the memory cell 6 and the source potential connection transistor 12. Therefore, it is possible to prevent the area of the memory cell array 1 from increasing.

Furthermore, the following effect is obtained by making the shape and the size of the source potential connection transistor diffusion layer 16 constituting the source potential connection transistor 12 being disposed so as to be dispersed inside the memory cell array 1, in the column direction, are the same as those of the diffusion layer of the memory cell transistor constituting each of the peripheral memory cells 6, in the column direction. The shape of the diffusion layer disposed in the source potential connection transistor 12, in the column direction, is the same as the pattern of the diffusion layer of each of multiple memory cells 6 disposed therearound. Hence, the patterning for creating the mask for the diffusion layers of the memory cell array 1, requiring particularly high accuracy during mask creation, can be facilitated. As a result, the yield of the device serving as an LSI chip provided with a memory core can be improved.

In this embodiment, it is described that the potential of the source potential wiring 13 is the ground potential. However, the potential is not limited to the ground potential.

Furthermore, in this embodiment, it is described that the source potential control circuit 5 is disposed inside the row decoder block 2. However, the configuration of this embodiment is not limited to the above-mentioned configuration. A similar or more significant effect can also be obtained by disposing the source potential control circuit 5 on the opposite side of the row decoder block 2 across the memory cell array 1 or on both sides thereof.

### Second Embodiment

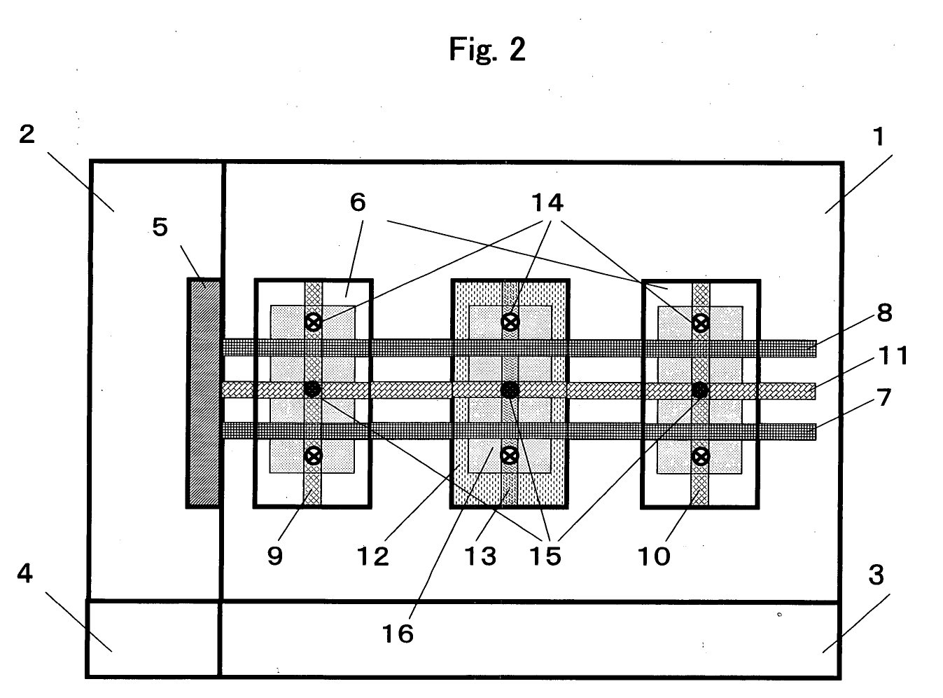

FIG. 2 is a layout diagram showing the configuration of a semiconductor memory device according to a second embodiment of the present invention.

In FIG. 2, the semiconductor memory device comprises components similar to those shown in FIG. 1.

In the row and column directions, i and j memory cells 6 are disposed, respectively, so as to constitute the memory cell array 1. The source potential connection transistor 12 is disposed for every constant number of the memory cells 6 in the column direction. The source potential control circuits 5, the memory cells 6 and the source potential connection transistors 12, j in number respectively, are disposed in the column direction. In addition, the sources are common in the word line (N-1 th) 7 and the word line (N th) 8. Furthermore, the source potential wiring 13 is connected to a ground power supply inside the memory core. Still further, the memory cell 6 and the source potential connection transistor 12 are each formed of an N-channel MOS transistor. Moreover, the shapes and the sizes of the source potential connection transistor diffusion layer constituting the source potential connection transistor 12, in the row and column directions, are the same as those of the diffusion layer of the memory cell transistor constituting the memory cell 6, in the row and column directions. Besides, the wiring width and the wiring pitch of the source potential wirings 13 are the same as the wiring width and the wiring pitch of the bit lines disposed inside the peripheral memory cells 6. Because the components described above are similar to those shown in FIG. 1, the same components are designated by the same numerals, and their descriptions are omitted.

The semiconductor memory device configured as described above will be described below.

When the word line (N th) 8 is selected using a row selection signal generated in the row decoder block 2, the potential of the source potential control signal line 11 is controlled to the ground potential using the row selection signal or the like in the source potential control circuit 5 connected to the word line (N-1 th) 7 and the word line (Nth) 8. Because the word line (N th) 8 is selected, the source potential connection transistor 12 is turned ON. Hence, the source potential control signal line 11 is connected to the ground potential. The bit line 9 in the cell in which the bit line contacts 14 are disposed beforehand in the memory cell transistor inside the memory cell 6 is also connected to the ground potential, and data “0” is read. On the other hand, the potential of the bit line in a cell in which the bit line contacts 14 are not disposed beforehand remains having a precharged potential, and data “1” is read.

At this time, the following effect is obtained because the source potential control circuit 5 is disposed inside the row decoder block 2, and because the source potential connection transistor 12 is disposed so as to be dispersed for every constant number of columns inside the memory cell array 1. When the number of the memory cells 6 being disposed increases in the row direction, that is, even when the length of the source potential control signal line 11 is extended, the potential of the source potential control signal line 11, at a position away from the source potential control circuits 5, can be quickly switched to the ground potential. As a result, more memory cells 6 to be disposed inside the memory cell array 1 can be disposed in the row direction, and the semiconductor memory device can be made larger in size.

In addition, because the source potential connection transistor 12 is formed of an N-channel MOS transistor as in the case of the memory cell transistor constituting the memory cell 6, it is not necessary to provide any MOS injection-separation region between the memory cell 6 and the source potential connection transistor 12. Therefore, it is possible to prevent the area of the memory cell array 1 from increasing.

Furthermore, the following effect is obtained by making the shapes and the sizes of the source potential connection transistor diffusion layer 16 constituting the source potential connection transistor 12 being disposed so as to be dispersed inside the memory cell array 1, in the row and column directions, are the same as those of the diffusion layer of the memory cell transistor constituting each of the peripheral memory cells 6, in the row and column directions. The shape of the diffusion layer disposed in the source potential connection transistor 12 is the same as the pattern of the diffusion layer of each of multiple memory cells 6 disposed therearound. Hence, the patterning for creating the mask for the diffusion layers of the memory cell array 1, requiring particularly high accuracy during mask creation, can be facilitated. In addition, the wiring layer, the wiring width and the wiring pitch of the source potential wirings 13 are configured so as to be the same as those of the bit lines of the peripheral memory cells 6. Hence, even in the wiring layers, data patterns can be made uniform inside the memory cell array 1, and the patterning for mask creation is facilitated. As a result, the yield of the device serving as an LSI chip provided with a memory core can be improved.

In this embodiment, it is described that the potential of the source potential wiring 13 is the ground potential. However, the potential is not limited to the ground potential.

Furthermore, in this embodiment, it is described that the source potential control circuit 5 is disposed inside the row decoder block 2. However, the configuration of this embodiment is not limited to the above-mentioned configuration. A similar or more significant effect can also be obtained by disposing the source potential control circuit 5 on the opposite side of the row decoder block 2 across the memory cell array 1 or on both sides thereof.

### Third Embodiment

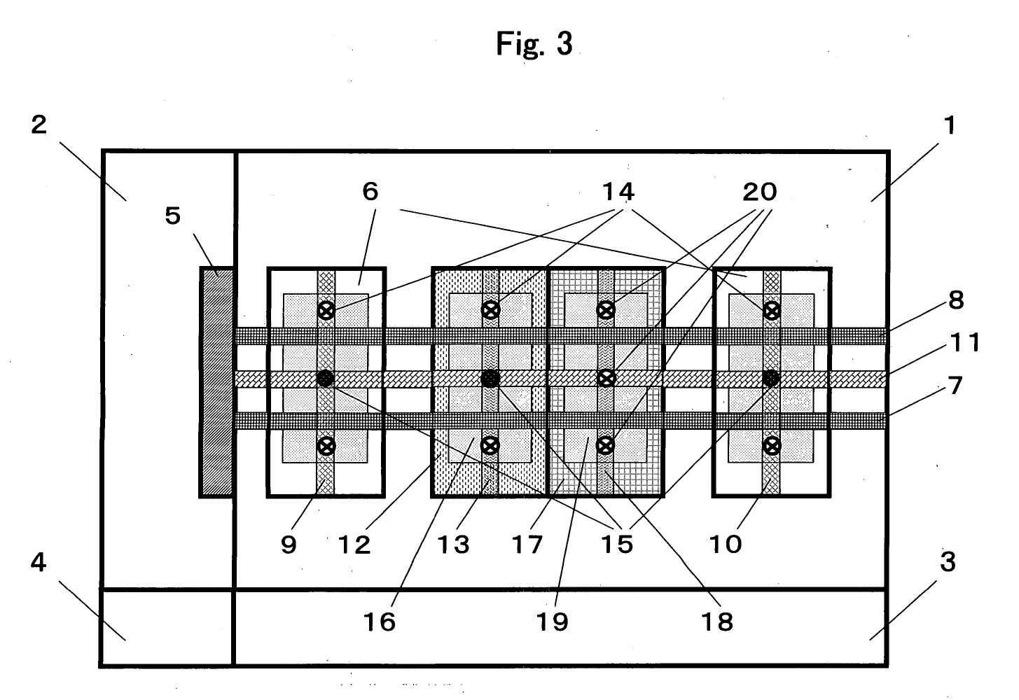

FIG. 3 is a layout diagram showing the configuration of a semiconductor memory device according to a third embodiment of the present invention.

In FIG. 3, the semiconductor memory device comprises the same components as those shown in FIG. 1, a substrate contact disposition cell 17, a ground power supply wiring 18, a substrate contact diffusion layer 19, and substrate contacts 20.

In the row and column directions, i and j memory cells 6 are disposed, respectively, so as to constitute the memory cell array 1. The source potential connection transistor 12 is disposed for every constant number of the memory cells 6 in the column direction. The source potential control circuits 5, the memory cells 6 and the source potential connection transistors 12, j in number respectively, are disposed in the column direction. In addition, the sources are common in the word line (N-1 th) 7 and the word line (N th) 8. Furthermore, the source potential wiring 13 is connected to a ground power supply inside the memory core. Still further, the memory cell 6 and the source potential connection transistor 12 are each formed of an N-channel MOS transistor. Moreover, the shapes and the sizes of the source potential connection transistor diffusion layer constituting the source potential connection transistor 12, in the row and column directions, are the same as those of the diffusion layer of the memory cell transistor constituting the memory cell 6, in the row and column directions. Besides, the wiring width and the wiring pitch of the source potential wirings 13 are the same as the wiring width and the wiring pitch of the bit lines disposed inside the peripheral memory cells 6. Still further, the substrate disposition cell 17 is disposed adjacent to the source potential connection transistor 12, and the sizes of the cell in the row and column directions are the same as those of the source potential connection transistor 12. Via the substrate contacts 20, the cell 17 is connected to the ground power supply wiring 18 disposed in the column direction inside the cell. The shapes of the substrate contact diffusion layer 19 in the row and column directions are the same as the shapes of the transistor diffusion layer constituting the adjacent memory cell 6 and the shapes of the source potential connection transistor diffusion layer 16 constituting the source potential connection transistor 12, in the row and column directions. In the above descriptions, the same components as those shown in FIG. 2 are designated by the same numerals, and their descriptions are omitted.

The semiconductor memory device configured as described above will be described below.

When the word line (N th) 8 is selected using a row selection signal generated in the row decoder block 2, the potential of the source potential control signal line 11 is controlled to the ground potential using the row selection signal or the like in the source potential control circuit 5 connected to the word line (N-1 th) 7 and the word line (Nth) 8. Because the word line (N th) 8 is selected, the source potential connection transistor 12 is turned ON. Hence, the source potential control signal line 11 is connected to the ground potential. The bit line 9 in the cell in which the bit line contacts 14 are disposed beforehand in the memory cell transistor inside the memory cell 6 is also connected to the ground potential, and data “0” is read. On the other hand, the potential of the bit line in a cell in which the bit line contacts 14 are not disposed beforehand remains having a precharged potential, and data “1” is read.

At this time, the following effect is obtained because the source potential control circuit 5 is disposed inside the row decoder block 2, and because the source potential connection transistor 12 is disposed so as to be dispersed for every constant number of columns inside the memory cell array 1. When the number of the memory cells 6 being disposed increases in the row direction, that is, even when the length of the source potential control signal line 11 is extended, the potential of the source potential control signal line 11, at a position away from the source potential control circuits 5, can be quickly switched to the ground potential. As a result, more memory cells 6 to be disposed inside the memory cell array 1 can be disposed in the row direction, and the semiconductor memory device can be made larger in size.

In addition, because the source potential connection transistor 12 is formed of an N-channel MOS transistor as in the case of the memory cell transistor constituting the memory cell 6, it is not necessary to provide any MOS injection-separation region between the memory cell 6 and the source potential connection transistor 12. Therefore, it is possible to prevent the area of the memory cell array 1 from increasing.

Furthermore, the following effect is obtained by making the shapes and the sizes of the source potential connection transistor diffusion layer 16 constituting the source potential connection transistor 12 being disposed so as to be dispersed inside the memory cell array 1, in the row and column directions, are the same as those of the diffusion layer of the memory cell transistor constituting each of the peripheral memory cells 6, in the row and column directions. The shape of the diffusion layer disposed in the source potential connection transistor 12 is the same as the pattern of the diffusion layer of each of multiple memory cells 6 disposed therearound. Hence, the patterning for creating the mask for the diffusion layers of the memory cell array 1, requiring particularly high accuracy during mask creation, can be facilitated. In addition, the wiring layer, the wiring width and the wiring pitch of the source potential wirings 13 are configured so as to be the same as those of the bit lines of the peripheral memory cells 6. Hence, even in the wiring layers, data patterns can be made uniform inside the memory cell array 1, and the patterning for mask creation is facilitated. As a result, the yield of the device serving as an LSI chip provided with a memory core can be improved.

Furthermore, because the substrate disposition cell 17 is disposed adjacent to the source potential connection transistor 12, the area reduction effect of this configuration can be made higher than that of the configuration in which the substrate disposition cell 17 and the source potential connection transistor 12 are disposed separately inside the memory cell array. In addition, the layout shapes of the substrate contact diffusion layer 19 constituting the substrate contact disposition cell 17 and the ground power supply wiring 18 are respectively made the same as the layout shapes of the transistor diffusion layer constituting the memory cell 6 and the bit line 13 being adjacent thereto respectively. With this configuration, the layout shape patterns of both the diffusion layer and the wiring layer at the position where the substrate arrangement cell 17 is disposed are not deformed. For this reason, the patterning for mask creation inside the memory cell array 1 is facilitated. As a result, the yield of the device serving as an LSI chip provided with a memory core can be improved.

In this embodiment, it is described that the potential of the source potential wiring 13 is the ground potential. However, the potential is not limited to the ground potential.

Furthermore, in this embodiment, it is described that the source potential control circuit 5 is disposed inside the row decoder block 2. However, the configuration of this embodiment is not limited to the above-mentioned configuration. A similar or more significant effect can also be obtained by disposing the source potential control circuit 5 on the opposite side of the row decoder block 2 across the memory cell array 1 or on both sides thereof.

### Fourth Embodiment

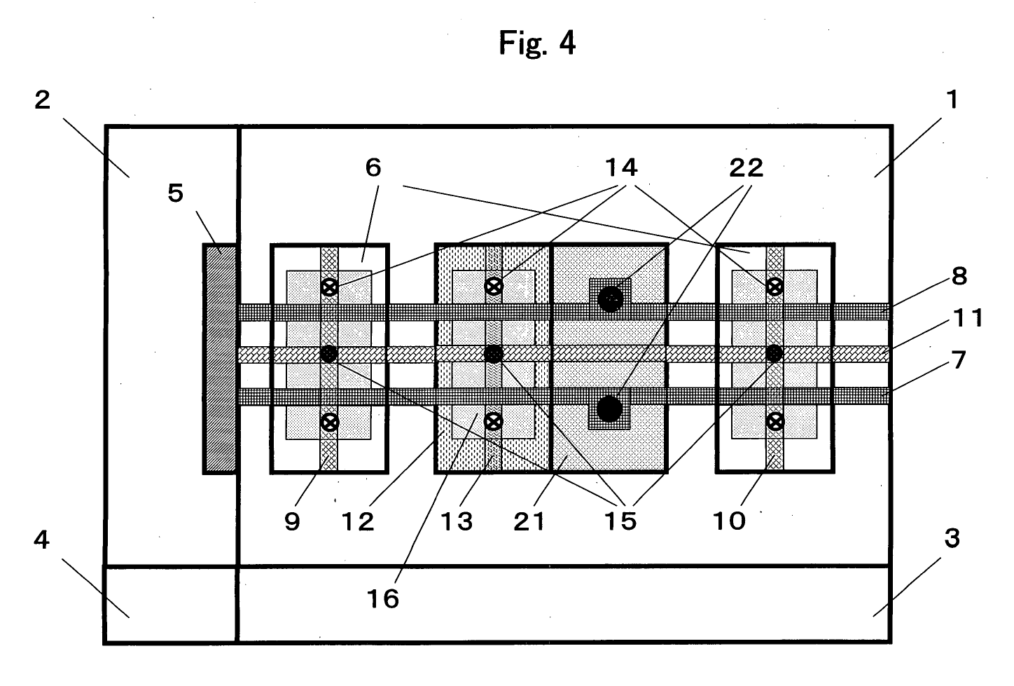

FIG. 4 is a layout diagram showing the configuration of a semiconductor memory device according to a fourth embodiment of the present invention.

In FIG. 4, the semiconductor memory device comprises the same components as those shown in FIG. 1, a back-wiring connection contact disposition cell 21, and back contacts 22.

In the row and column directions, i and j memory cells 6 are disposed, respectively, so as to constitute the memory cell array 1. The source potential connection transistor 12 is disposed for every constant number of the memory cells 6 in the column direction. The source potential control circuits 5, the memory cells 6 and the source potential connection transistors 12, j in number respectively, are disposed in the column direction. In addition, the sources are common in the word line (N-1 th) 7 and the word line (N th) 8. Furthermore, the source potential wiring 13 is connected to a ground power supply inside the memory core. Still further, the memory cell 6 and the source potential connection transistor 12 are each formed of an N-channel MOS transistor. Moreover, the shapes and the sizes of the source potential connection transistor diffusion layer constituting the source potential connection transistor 12, in the row and column directions, are the same as those of the diffusion layer of the memory cell transistor constituting the memory cell 6, in the row and column directions. Besides, the wiring width and the wiring pitch of the source potential wirings 13 are the same as the wiring width and the wiring pitch of the bit lines disposed inside the peripheral memory cells 6. The back contacts 22 are contacts being used to connect the word line (N-1 th) 7 and the word line (N th) 8 to the back wiring disposed on a upper wiring layer to reduce wiring resistance. In the above descriptions, the same components as those shown in FIG. 2 are designated by the same numerals, and their descriptions are omitted.

The semiconductor memory device configured as described above will be described below.

When the word line (N th) 8 is selected using a row selection signal generated in the row decoder block 2, the potential of the source potential control signal line 11 is controlled to the ground potential using the row selection signal or the like in the source potential control circuit 5 connected to the word line (N-1 th) 7 and the word line (Nth) 8. Because the word line (N th) 8 is selected, the source potential connection transistor 12 is turned ON. Hence, the source potential control signal line 11 is connected to the ground potential. The bit line 9 in the cell in which the bit line contacts 14 are disposed beforehand in the memory cell transistor inside the memory cell 6 is also connected to the ground potential, and data “0” is read. On the other hand, the potential of the bit line in a cell in which the bit line contacts 14 are not disposed beforehand remains having a precharged potential, and data “1” is read.

At this time, the following effect is obtained because the source potential control circuit 5 is disposed inside the row decoder block 2, and because the source potential connection transistor 12 is disposed so as to be dispersed for every constant number of columns inside the memory cell array 1. When the number of the memory cells 6 being disposed increases in the row direction, that is, even when the length of the source potential control signal line 11 is extended, the potential of the source potential control signal line 11, at a position away from the source potential control circuits 5, can be quickly switched to the ground potential. As a result, more memory cells 6 to be disposed inside the memory cell array 1 can be disposed in the row direction, and the semiconductor memory device can be made larger in size.

In addition, because the source potential connection transistor 12 is formed of an N-channel MOS transistor as in the case of the memory cell transistor constituting the memory cell 6, it is not necessary to provide any MOS injection-separation region between the memory cell 6 and the source potential connection transistor 12. Therefore, it is possible to prevent the area of the memory cell array 1 from increasing.

Furthermore, the following effect is obtained by making the shapes and the sizes of the source potential connection transistor diffusion layer 16 constituting the source potential connection transistor 12 being disposed so as to be dispersed inside the memory cell array 1, in the row and column directions, are the same as those of the diffusion layer of the memory cell transistor constituting each of the peripheral memory cells 6, in the row and column directions. The shape of the diffusion layer disposed in the source potential connection transistor 12 is the same as the pattern of the diffusion layer of each of multiple memory cells 6 disposed therearound. Hence, the patterning for creating the mask for the diffusion layers of the memory cell array 1, requiring particularly high accuracy during mask creation, can be facilitated. In addition, the wiring layer, the wiring width and the wiring pitch of the source potential wirings 13 are configured so as to be the same as those of the bit lines of the peripheral memory cells 6. Hence, even in the wiring layers, data patterns can be made uniform inside the memory cell array 1, and the patterning for mask creation is facilitated. As a result, the yield of the device serving as an LSI chip provided with a memory core can be improved.

Furthermore, because the back-wiring connection contact disposition cell 21 is disposed adjacent to the source potential connection transistor 12, the area reduction effect of this configuration can be made higher than that of the configuration in which the disposition cell 21 and the source potential connection transistor 12 are disposed separately.

In this embodiment, it is described that the potential of the source potential wiring 13 is the ground potential. However, the potential is not limited to the ground potential.

Furthermore, in this embodiment, it is described that the source potential control circuit 5 is disposed inside the row decoder block 2. However, the configuration of this embodiment is not limited to the above-mentioned configuration. A similar or more significant effect can also be obtained by disposing the source potential control circuit 5 on the opposite side of the row decoder block 2 across the memory cell array 1 or on both sides thereof.

### Fifth Embodiment

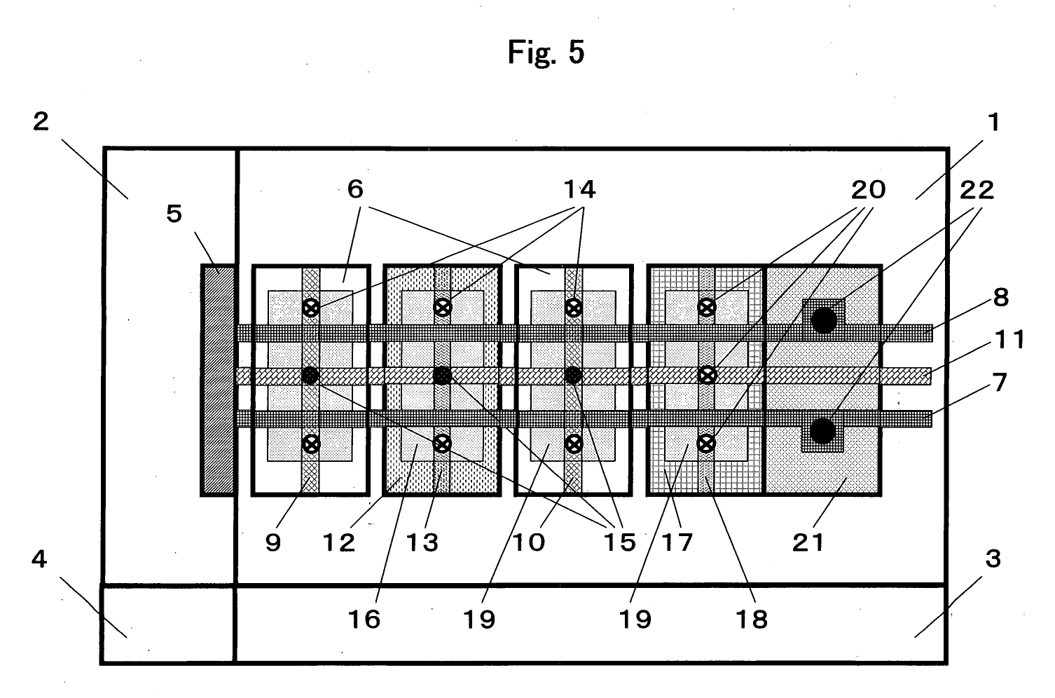

FIG. 5 is a layout diagram showing the configuration of a semiconductor memory device according to a fifth embodiment of the present invention.

In FIG. 5, the semiconductor memory device comprises the same components as those shown in FIG. 1, a substrate contact disposition cell 17, a ground power supply wiring 18, a substrate contact diffusion layer 19, substrate contacts 20, a back-wiring connection contact disposition cell 21, and back contacts 22.

In the row and column directions, i and j memory cells 6 are disposed, respectively, so as to constitute the memory cell array 1. The source potential connection transistor 12 is disposed for every constant number of the memory cells 6 in the column direction. The source potential control circuits 5, the memory cells 6 and the source potential connection transistors 12, j in number respectively, are disposed in the column direction. In addition, the sources are common in the word line (N-1 th) 7 and the word line (N th) 8. Furthermore, the source potential wiring 13 is connected to a ground power supply inside the memory core. Still further, the memory cell 6 and the source potential connection transistor 12 are each formed of an N-channel MOS transistor. Moreover, the shapes and the sizes of the source potential connection transistor diffusion layer constituting the source potential connection transistor 12, in the row and column directions, are the same as those of the diffusion layer of the memory cell transistor constituting the memory cell 6, in the row and column directions. Besides, the wiring width and the wiring pitch of the source potential wirings 13 are the same as the wiring width and the wiring pitch of the bit lines disposed inside the peripheral memory cells 6. Furthermore, the substrate contact disposition cell 17, together with the back-wiring connection contact disposition cell 21, and the source potential connection transistor 12 are disposed alternately for every constant number of the memory cells in the column direction, and the sizes of the cell in the row and column directions are the same as those of the source potential connection transistor 12. Via the substrate contacts 20, the cell 17 is connected to the ground power supply wiring 18 disposed in the column direction inside the cell. The shapes of the substrate contact diffusion layer 19 in the row and column directions are the same as the shapes of the transistor diffusion layer constituting the adjacent memory cell 6 and the shapes of the source potential connection transistor diffusion layer 16 constituting the source potential connection transistor 12, in the row and column directions. The back contacts 22 are contacts being used to connect the word line (N-1 th) 7 and the word line (N th) 8 to the back wiring disposed on a upper wiring layer to reduce wiring resistance. In the above descriptions, the same components as those shown in FIGS. 3 and 4 are designated by the same numerals, and their descriptions are omitted.

The semiconductor memory device configured as described above will be described below.

When the word line (N th) 8 is selected using a row selection signal generated in the row decoder block 2, the potential of the source potential control signal line 11 is controlled to the ground potential using the row selection signal or the like in the source potential control circuit 5 connected to the word line (N-1 th) 7 and the word line (Nth) 8. Because the word line (N th) 8 is selected, the source potential connection transistor 12 is turned ON. Hence, the source potential control signal line 11 is connected to the ground potential. The bit line 9 in the cell in which the bit line contacts 14 are disposed beforehand in the memory cell transistor inside the memory cell 6 is also connected to the ground potential, and data “0” is read. On the other hand, the potential of the bit line in a cell in which the bit line contacts 14 are not disposed beforehand remains having a precharged potential, and data “1” is read.

At this time, the following effect is obtained because the source potential control circuit 5 is disposed inside the row decoder block 2, and because the source potential connection transistor 12 is disposed so as to be dispersed for every constant number of columns inside the memory cell array 1. When the number of the memory cells 6 being disposed increases in the row direction, that is, even when the length of the source potential control signal line 11 is extended, the potential of the source potential control signal line 11, at a position away from the source potential control circuits 5, can be quickly switched to the ground potential. As a result, more memory cells 6 to be disposed inside the memory cell array 1 can be disposed in the row direction, and the semiconductor memory device can be made larger in size.

In addition, because the source potential connection transistor 12 is formed of an N-channel MOS transistor as in the case of the memory cell transistor constituting the memory cell 6, it is not necessary to provide any MOS injection-separation region between the memory cell 6 and the source potential connection transistor 12. Therefore, it is possible to prevent the area of the memory cell array 1 from increasing.

Furthermore, the following effect is obtained by making the shapes and the sizes of the source potential connection transistor diffusion layer 16 constituting the source potential connection transistor 12 being disposed so as to be dispersed inside the memory cell array 1, in the row and column directions, are the same as those of the diffusion layer of the memory cell transistor constituting each of the peripheral memory cells 6, in the row and column directions. The shape of the diffusion layer disposed in the source potential connection transistor 12 is the same as the pattern of the diffusion layer of each of multiple memory cells 6 disposed therearound. Hence, the patterning for creating the mask for the diffusion layers of the memory cell array 1, requiring particularly high accuracy during mask creation, can be facilitated. In addition, the wiring layer, the wiring width and the wiring pitch of the source potential wirings 13 are configured so as to be the same as those of the bit lines of the peripheral memory cells 6. Hence, even in the wiring layers, data patterns can be made uniform inside the memory cell array 1, and the patterning for mask creation is facilitated. As a result, the yield of the device serving as an LSI chip provided with a memory core can be improved.

Furthermore, the following effect is obtained by alternately disposing the substrate contact disposition cell 17, together with the back-wiring connection contact disposition cell 21, and the source potential connection transistor 12 for every constant number of the memory cells in the column direction. Hence, even when a separation region in which injection being different from the injection for the memory cells 6 is carried out is required to dispose the substrate contacts 20, the separation region can be used as a space in which the back wiring contacts are disposed. Therefore, the influence of area increase can be suppressed. In addition, the layout shapes of the substrate contact diffusion layer 19 constituting the substrate contact disposition cell 17 and the ground power supply wiring 18 are respectively made the same as the layout shapes of the transistor diffusion layer constituting the memory cell 6 and the bit line 13 being adjacent thereto respectively. With this configuration, the layout shape patterns of both the diffusion layer and the wiring layer at the position where the substrate arrangement cell 17 is disposed are not deformed. For this reason, the patterning for mask creation inside the memory cell array 1 is facilitated. As a result, the yield of the device serving as an LSI chip provided with a memory core can be improved.

In this embodiment, it is described that the potential of the source potential wirings 13 is the ground potential. However, the potential is not limited to the ground potential.

Furthermore, in this embodiment, it is described that the source potential control circuit 5 is disposed inside the row decoder block 2. However, the configuration of this embodiment is not limited to the above-mentioned configuration. A similar or more significant effect can also be obtained by disposing the source potential control circuit 5 on the opposite side of the row decoder block 2 across the memory cell array 1 or on both sides thereof.

### Sixth Embodiment

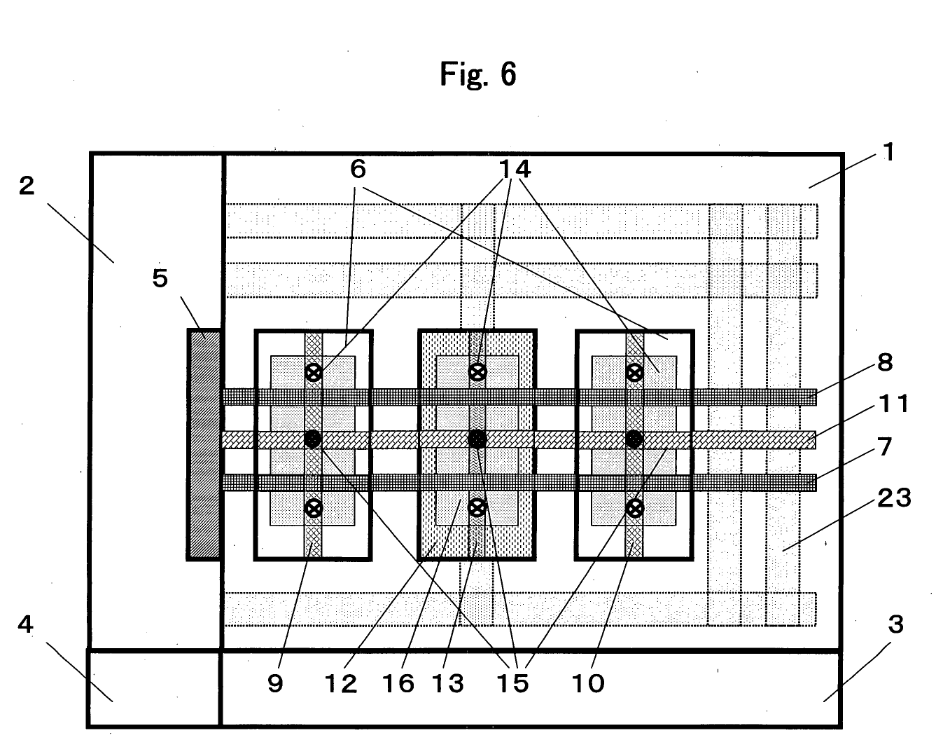

FIG. 6 is a layout diagram showing the configuration of a semiconductor memory device according to a sixth embodiment of the present invention.

In FIG. 6, the semiconductor memory device comprises the same components as those shown in FIG. 1, and source potential mesh wirings 23.

In the row and column directions, i and j memory cells 6 are disposed, respectively, so as to constitute the memory cell array 1. The source potential connection transistor 12 is disposed for every constant number of the memory cells 6 in the column direction. The source potential control circuits 5, the memory cells 6 and the source potential connection transistors 12, j in number respectively, are disposed in the column direction. In addition, the sources are common in the word line (N-1 th) 7 and the word line (N th) 8. Furthermore, the source potential wiring 13 is connected to a ground power supply inside the memory core. Still further, the memory cell 6 and the source potential connection transistor 12 are each formed of an N-channel MOS transistor. Moreover, the shapes and the sizes of the source potential connection transistor diffusion layer constituting the source potential connection transistor 12, in the row and column directions, are the same as those of the diffusion layer of the memory cell transistor constituting the memory cell 6, in the row and column directions. Besides, the wiring width and the wiring pitch of the source potential wirings 13 are the same as the wiring width and the wiring pitch of the bit lines disposed inside the peripheral memory cells 6. Still further, the substrate disposition cell 17 is disposed adjacent to the source potential connection transistor 12, and the sizes of the cell in the row and column directions are the same as those of the source potential connection transistor 12. Via the substrate contacts 20, the cell 17 is connected to the ground power supply wiring 18 disposed in the column direction inside the cell. The shapes of the substrate contact diffusion layer 19 in the row and column directions are the same as the shapes of the transistor diffusion layer constituting the adjacent memory cell 6 and the shapes of the source potential connection transistor diffusion layer 16 constituting the source potential connection transistor 12, in the row and column directions. The source potential mesh wirings 23 are disposed in a mesh form using multiple wiring layers or a single wiring layer inside the memory cell array 1, and are connected to the source potential wirings 13 and the ground power supply. In the above descriptions, the same components as those shown in FIG. 2 are designated by the same numerals, and their descriptions are omitted.

The semiconductor memory device configured as described above will be described below.

When the word line (N th) 8 is selected using a row selection signal generated in the row decoder block 2, the potential of the source potential control signal line 11 is controlled to the ground potential using the row selection signal or the like in the source potential control circuit 5 connected to the word line (N-1 th) 7 and the word line (Nth) 8. Because the word line (N th) 8 is selected, the source potential connection transistor 12 is turned ON. Hence, the source potential control signal line 11 is connected to the ground potential. The bit line 9 in the cell in which the bit line contacts 14 are disposed beforehand in the memory cell transistor inside the memory cell 6 is also connected to the ground potential, and data “0” is read. On the other hand, the potential of the bit line in a cell in which the bit line contacts 14 are not disposed beforehand remains having a precharged potential, and data “1” is read.

At this time, the following effect is obtained because the source potential control circuit 5 is disposed inside the row decoder block 2, and because the source potential connection transistor 12 is disposed so as to be dispersed for every constant number of columns inside the memory cell array 1. When the number of the memory cells 6 being disposed increases in the row direction, that is, even when the length of the source potential control signal line 11 is extended, the potential of the source potential control signal line 11, at a position away from the source potential control circuits 5, can be quickly switched to the ground potential. As a result, more memory cells 6 to be disposed inside the memory cell array 1 can be disposed in the row direction, and the semiconductor memory device can be made larger in size.

In addition, because the source potential connection transistor 12 is formed of an N-channel MOS transistor as in the case of the memory cell transistor constituting the memory cell 6, it is not necessary to provide any MOS injection-separation region between the memory cell 6 and the source potential connection transistor 12. Therefore, it is possible to prevent the area of the memory cell array 1 from increasing.

Furthermore, the following effect is obtained by making the shapes and the sizes of the source potential connection transistor diffusion layer 16 constituting the source potential connection transistor 12 being disposed so as to be dispersed inside the memory cell array 1, in the row and column directions, are the same as those of the diffusion layer of the memory cell transistor constituting each of the peripheral memory cells 6, in the row and column directions. The shape of the diffusion layer disposed in the source potential connection transistor 12 is the same as the pattern of the diffusion layer of each of multiple memory cells 6 disposed therearound. Hence, the patterning for creating the mask for the diffusion layers of the memory cell array 1, requiring particularly high accuracy during mask creation, can be facilitated. In addition, the wiring layer, the wiring width and the wiring pitch of the source potential wirings 13 are configured so as to be the same as those of the bit lines of the peripheral memory cells 6. Hence, even in the wiring layers, data patterns can be made uniform inside the memory cell array 1, and the patterning for mask creation is facilitated. As a result, the yield of the device serving as an LSI chip provided with a memory core can be improved.

Furthermore, the source potential mesh wirings 23 are disposed in a mesh form using multiple wiring layers in both the row and column directions inside the memory cell array 1, and connected to the source potential wirings 13 at positions, such as the upper portion of the source potential connection transistor 12 and the end portions of the memory cell array 1. With this configuration, the ground power supply can be supplied to the source potential wirings 13 inside the memory cell array 1 through low resistances.

In this embodiment, it is described that the potential of the source potential wirings 13 is the ground potential. However, the potential is not limited to the ground potential.

Furthermore, in this embodiment, it is described that the source potential control circuit 5 is disposed inside the row decoder block 2. However, the configuration of this embodiment is not limited to the above-mentioned configuration. A similar or more significant effect can also be obtained by disposing the source potential control circuit 5 on the opposite side of the row decoder block 2 across the memory cell array 1 or on both sides thereof.

### Seventh Embodiment

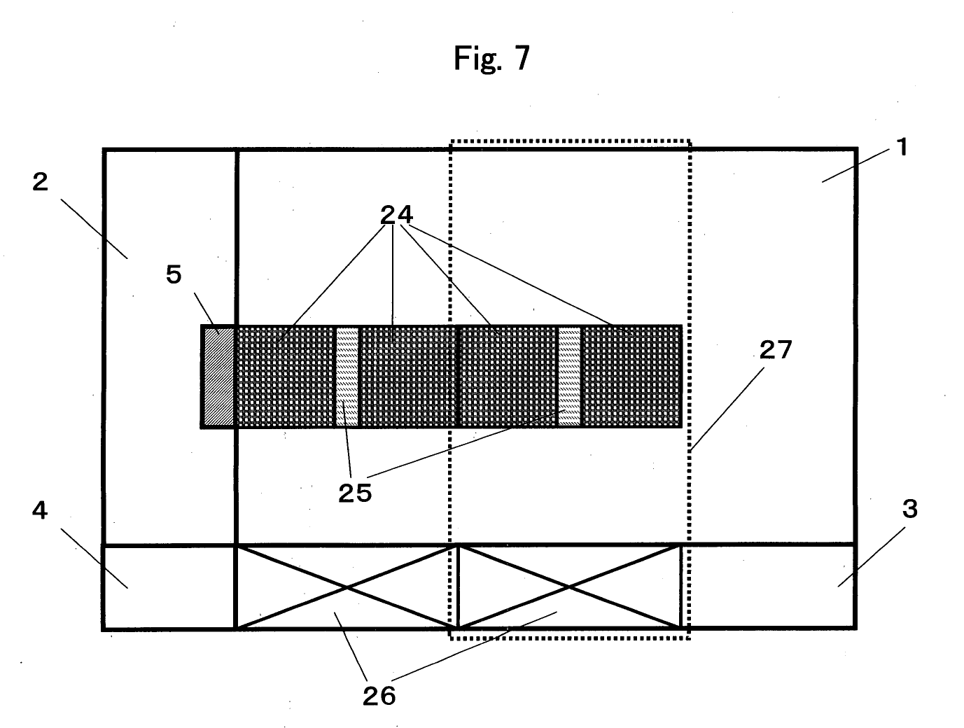

FIG. 7 is a layout diagram showing the configuration of a semiconductor memory device according to a seventh embodiment of the present invention.

In FIG. 7, the semiconductor memory device comprises a memory cell array 1, a row decoder block 2, a data router block 3, a peripheral control circuit 4, a source potential control circuit 5, memory cell blocks 24, source potential connection transistor circuits 25, data output unit circuits 26, and data output unit blocks 27.

The memory cell block 24 is a block in which k and l memory cells 6, shown in FIG. 2, are disposed in the row and column directions, respectively. Furthermore, m and n memory cell blocks 24 are disposed in the row and column directions, respectively, thereby forming the memory cell array 1. The source potential connection transistor circuit 25 is a circuit block in which l source potential connection transistors 12, shown in FIG. 2, are disposed in the column direction, and the source potential connection transistor circuit 25 is disposed between the memory cell blocks 24. The data output unit circuits 26 are disposed inside the data router block 3. The data output unit circuit 26 is a minimum unit block constituting one unit that is used to decode data on multiple bit lines and to output the decoded data as a piece of memory data. The data output unit block 27 comprises the data output unit circuit 26, and the memory cell blocks 24 and the source potential connection transistor circuit 25 corresponding to the data output unit circuit 26. The data output unit block 27 is a minimum unit block constituting one unit that is used to output memory data to the outside of the memory. With respect to the above descriptions, the same components as those shown in FIG. 2 are designated by the same numerals, and their descriptions are omitted.

The semiconductor memory device configured as described above will be described below.

The source potential connection transistor circuit 25 comprising the source potential connection transistors 12 according to the second embodiment of the present invention corresponds to the data output unit block 27, which outputs unit data as memory data, in one-to-one correspondence, and is disposed inside the memory core. Hence, even when the number of data output units, that is, the memory capacity of the memory core, is increased or decreased in units, because one source potential connection transistor circuit 25 is disposed in each data output unit block 27, the source potential can be controlled for each unit block, and the memory cell array 1 is compiled easily.

Still further, in this embodiment, an example in which one source potential connection transistor circuit 25 is disposed in each data output unit block 27 is shown. However, the configuration of this embodiment is not limited to this configuration. Effects similar to or more significant than the above-mentioned effects can be obtained even when multiple source potential connection transistor circuits 25 are disposed.

### INDUSTRIAL APPLICABILITY

In the semiconductor memory device according to the present invention, the number of memory cells per word line to be connected to the gates of the memory cells can be increased, whereby the present invention is useful for reducing the area of the semiconductor memory device.

Furthermore, the present invention is useful for facilitating the mask pattern creation for the memory cell array, which requires microfabrication, by uniforming the patterning of the diffusion layers inside the memory core.

1. A semiconductor memory device comprising:
a memory cell array in which multiple memory cells, each including a memory cell transistor, are disposed in a matrix form in the row and column directions,
word lines, each of which is commonly connected to each row of the gates of said memory cell transistors included in said multiple memory cells,
bit lines, each of which is commonly connected to each column of the drains of said memory cell transistors included in said multiple memory cells,
source lines, each of which is commonly connected to each row of the sources of said memory cell transistors included in said multiple memory cells,
a source potential control circuit that selectively controls the potentials of said source lines according to a row selection signal that is used to select said word lines,
source potential supplying lines disposed in the column direction inside said memory cell array to supply the potentials controlled using said source potential control circuit to said memory cell array, and
source potential connection transistors, the drains of which are connected to said source potential supplying lines, the sources of which are connected to said source lines, and which selectively control the potentials of said source lines according to said row selection signal, wherein
said source potential control circuit controls the potentials of said source lines connected to said memory cells not selected using said row selection signal to potentials different from the potential of said source line connected to said memory cell selected using the row selection signal so that the off-leak currents of said memory cell transistors included in said non-selected memory cells are decreased,
said source potential supplying line and said source potential connection transistor are disposed between said memory cells disposed in the row direction, and also disposed for every constant number of said memory cells in the column direction, and
the shape of the diffusion layer constituting said source potential connection transistor in the column direction is the same as the shape of the diffusion layer constituting said memory cell in the column direction.

2. The semiconductor memory device according to claim 1, wherein said source potential connection transistor is a transistor comprising a diffusion layer obtained by carrying out the same injection as that for said memory cell transistor.

3. The semiconductor memory device according to claim 1, wherein
a row decoder including a circuit that creates said row selection signal being used to select said word lines is disposed adjacent to said memory cell array, and
said source potential control circuits are disposed at multiple positions inside said row decoder block and on the opposite side of said row decoder block across said memory cell array.

4. The semiconductor memory device according to claim 1, wherein the substrate contacts of said memory cell transistor are disposed inside said memory cell array in the column direction, the shape of the diffusion layer in the column direction on which said substrate contacts are disposed is the same as the shape of the diffusion layer of said memory cell transistor in the column direction, and said source potential connection transistor is disposed at the same position as that of the substrate contact wiring that is disposed inside said memory cell array in the column direction as a wiring for connecting said substrate contacts.

5. The semiconductor memory device according to claim 1, wherein a word line back-wiring is disposed to reduce the wiring resistances of said word lines, the connection contact regions for connecting said word line back-wirings to said word lines are disposed inside said memory cell array in the column direction, and said source potential connection transistors are disposed at the same positions as those of said connection contact regions.

6. The semiconductor memory device according to claim 1, wherein the substrate contacts of said memory cell transistor are disposed inside said memory cell array in the column direction, a word line back-wiring is disposed to reduce the wiring resistances of said word lines, the connection contact regions for connecting said word line back-wirings to said word lines are disposed inside said memory cell array in the column direction, the shape of the diffusion layer in the column direction on which said substrate contacts are disposed is the same as the shape of the diffusion layer of said memory cell transistor in the column direction, and said source potential connection transistors and the substrate contact wirings being disposed inside said memory cell array in the column direction and serving as said substrate contacts are disposed alternately for every constant number of rows.

7. The semiconductor memory device according to claim 1, wherein the potential supplied to said source line connected to said memory cell selected using said row selection signal in said source potential control circuit is set to the ground potential.

8. The semiconductor memory device according to claim 1, wherein the potential supplied to said source line connected to said memory cell selected using said row selection signal in said source potential control circuit is supplied from mesh wirings formed of one wiring layer disposed inside said memory cell array.

9. The semiconductor memory device according to claim 1, wherein the potential supplied to said source line connected to said memory cell selected using said row selection signal in said source potential control circuit is supplied from mesh wirings formed of multiple wiring layers disposed inside said memory cell array.

10. The semiconductor memory device according to claim 1, wherein the shapes of the diffusion layer constituting said source potential connection transistor, in the row and column directions, are the same as the shapes of the diffusion layer constituting said memory cell transistor, in the row and column directions.

11. The semiconductor memory device according to claim 4, wherein the shapes of the diffusion layer constituting said source potential connection transistor, in the row and column directions, are the same as the shapes of the diffusion layer constituting said memory cell transistor, in the row and column directions.

12. The semiconductor memory device according to claim 6, wherein the shapes of the diffusion layer constituting said source potential connection transistor, in the row and column directions, are the same as the shapes of the diffusion layer constituting said memory cell transistor, in the row and column directions.

13. The semiconductor memory device according to claim 4, wherein the shapes of the diffusion layer on which said substrate contacts are disposed, in the row and column directions, are the same as the shapes of the diffusion layer of said memory cell transistor, in the row and column directions.

14. The semiconductor memory device according to claim 6, wherein the shapes of the diffusion layer on which said substrate contacts are disposed, in the row and column directions, are the same as the shapes of the diffusion layer of said memory cell transistor, in the row and column directions.

15. The semiconductor memory device according to claim 1, wherein the shape of the diffusion layer constituting said source potential connection transistor, and the wiring width and pitch of the wiring layers constituting said source potential supplying lines are the same as the shape of the diffusion layer of said memory cell, and the wiring width and pitch of the wiring layers of said bit lines.

16. The semiconductor memory device according to claim 1, wherein one or more said source potential connection transistors are disposed in a data output unit block for said memory cells.
